(19) United States
(12) Patent Application Publication
(10) Pub. No.: US 2026/0106391 A1
(43) Pub. Date: Apr. 16, 2026

(54) ELECTRICAL CONNECTOR

(71) Applicant: Sichuan Huafeng Technology Co., Ltd., Mianyang (CN)

(72) Inventors: Jinpeng QIAN, Mianyang (CN); Cheng DONG, Mianyang (CN); Qijin YI, Mianyang (CN); Jianwen XU, Mianyang (CN)

(21) Appl. No.: 19/357,154

(22) Filed: Oct. 14, 2025

(30) Foreign Application Priority Data
Oct. 14, 2024 (CN) 202411433679.3

(51) Int. Cl. H01R 12/71; H01R 13/10; H01R 13/50; H01R 13/631

(52) U.S. Cl. CPC H01R 12/716; H01R 13/10; H01R 13/50; H01R 13/631

(57) ABSTRACT

An electrical connector includes a connector body, multiple regions are separated on the connector body, multiple terminal slots are arranged in each region, terminal slots in two adjacent regions are of mirror symmetry, the terminal slot is configured to enable an electrical contact to be inserted, and the electrical contact is configured to be electrically connected to the chip module. By designing the terminal slots in two adjacent regions into a mirror-symmetry configuration, the overall warpage form of the electrical connector is manifested as a twisted configuration along the length and width directions of the electrical connector.

### CROSS-REFERENCE TO RELATED APPLICATION

This application claims priority to Chinese Patent Application No. 202411433679.3 filed October 14, 2024, the disclosure of which is incorporated herein by reference in its entirety.

### TECHNICAL FIELD

The present disclosure relates to the field of connectors and, in particular, to an electrical connector.

### BACKGROUND

An electrical connector is used for achieving the electrical connection between a chip module and a circuit board. The electrical connector mainly includes a connector body. The connector body is divided into multiple blocks, multiple terminal slots are arranged in each block, and the terminal slots are used for the insertion of electrical contacts.

In the related art, as shown in FIGS. 1 and 2, which are simplified schematic views of an electrical connector, the connector body 1′ is partitioned into four blocks as an example. In FIG. 1, the terminal slot 2′ in the upper-left block is identical in structure to the terminal slot 2′ in the upper-right section, and the two the terminal slots 2′ may be formed by translational symmetry; the terminal slot 2′ in the upper-left block and the terminal slot 2′ in the lower-left block are formed by rotating counterclockwise around the center of the connector body 1′. The preceding layout causes the molded electrical connector to twist about its diagonal direction (as indicated by the dashed line in FIG. 2), resulting in a warpage pattern of twisting at four corners for the electrical connector. Such a warpage pattern of the electrical connector is extremely difficult to rectify in subsequent processes. Especially for electrical connectors having a large number of terminal slots (exceeding 4000 pins), the warpage of these products must be controlled within 0.20 mm, and excessive warpage may lead to missing soldering in subsequent processing processes, thereby increasing the product defect rate.

Therefore, there is an urgent need for an electrical connector to solve the preceding problems.

### SUMMARY

In view of the preceding problems, the object of the present disclosure is to provide an electrical connector to effectively control the warpage of the electrical connector, prevent the occurrence of missing soldering in subsequent processes, and improve the production yield of the products.

To achieve the preceding object, the present disclosure adopts the technical solutions below.

An electrical connector is provided. The electrical connector includes a connector body. Multiple regions are separated on the connector body. Multiple terminal slots are arranged in each region. Terminal slots in two adjacent regions are of mirror symmetry. The terminal slot is configured to enable an electrical contact to be inserted, and the electrical contact is configured to be electrically connected to a chip module.

As a preferred solution of the electrical connector of the present disclosure, the multiple regions include a first region, a second region, a third region and a fourth region. The connector body is provided with first support ribs arranged between the first region and the second region and between the third region and the fourth region, and the first support rib is used for supporting the chip module; and/or the connector body is provided with second support ribs arranged between the second region and the third region and between the first region and the fourth region, and the second support rib is used for supporting the chip module.

As a preferred solution of the electrical connector of the present disclosure, multiple first avoidance grooves are arranged on both sides of the second support rib, and the first avoidance groove is configured to avoid the head portion of the electrical contact.

Alternatively, the second support rib is provided with multiple first relief grooves at intervals along an extending direction thereof, and the first relief groove is used for balancing the torque of the connector body.

As a preferred solution of the electrical connector of the present disclosure, a convex rim protrudes from an outer periphery of the connector body upward toward the chip module, multiple second relief grooves are arranged on the convex rim, and the second relief groove is used for balancing the torque of the connector body.

As a preferred solution of the electrical connector of the present disclosure, a support boss is arranged on the terminal slot, and the support boss is used for supporting the chip module.

As a preferred solution of the electrical connector of the present disclosure, the connector body is provided with an avoidance hole, the avoidance hole is configured to avoid an electric component on the chip module or to avoid an electric component on a circuit board, a first support protrusion is arranged circumferentially around the avoidance hole on a surface of the connector body facing the chip module, the first support protrusion is used for supporting the chip module, a second support protrusion is arranged circumferentially around the avoidance hole on a surface of the connector body facing the circuit board, and the second support protrusion is used for supporting the circuit board.

As a preferred solution of the electrical connector of the present disclosure, a positioning protrusion is arranged at a corner position of the connector body, and the positioning protrusion is used for positioning the mounting position of the chip module.

As a preferred solution of the electrical connector of the present disclosure, multiple third support protrusions are arranged on a surface of the connector body away from the chip module, and the third support protrusion is configured to support the circuit board.

As a preferred solution of the electrical connector of the present disclosure, an indication structure is arranged in the connector body, and the indication structure is configured to indicate the mounting direction of the chip module.

As a preferred solution of the electrical connector of the present disclosure, a chamfer is arranged at the corner position of the connector body.

The present disclosure has the following beneficial effects.

In the electrical connector provided by the present disclosure, by designing the terminal slots in two adjacent regions of the connector body into a mirror-symmetry configuration, the overall warpage form of the molded electrical connector is manifested as a twisted configuration along the length and width directions of the electrical connector. Compared with the asymmetrical diagonal twisted configuration of existing electrical connectors, the twisted configuration along the length and width directions is easier to correct during subsequent warpage rectification, the connector body has a larger improvement space, and the warpage pattern of the finished product after the electrical contacts are inserted has less variation, thereby preventing the occurrence of missing soldering in subsequent soldering processes, avoiding poor soldering, effectively improving the production yield of the electrical connector products, and reducing the production cost of the products.

### BRIEF DESCRIPTION OF DRAWINGS

To illustrate technical solutions in embodiments of the present disclosure more clearly, the drawings used in the description of the embodiments of the present disclosure are briefly described below. Apparently, the drawings described below illustrate only part of the embodiments of the present disclosure, and those of ordinary skill in the art may obtain other drawings based on the content of the embodiments of the present disclosure and the drawings on the premise that no creative work is done.

FIG. 1 is a simplified schematic view illustrating the arrangement of multiple terminal slots of an electrical connector in the related art;

FIG. 2 is a simplified schematic view illustrating the stress-induced twisting of the electrical connector in the related art;

FIG. 3 is a first structure view of an electrical connector provided by a specific embodiment of the present disclosure;

FIG. 4 is a partial enlarged view of part A in FIG. 3;

FIG. 5 is a first top view of the electrical connector provided by a specific embodiment of the present disclosure;

FIG. 6 is a partial enlarged view of part B in FIG. 5;

FIG. 7 is a partial enlarged view of part C in FIG. 5;

FIG. 8 is a partial enlarged view of part D in FIG. 5;

FIG. 9 is a second top view of the electrical connector provided by a specific embodiment of the present disclosure;

FIG. 10 is a three top view of the electrical connector provided by a specific embodiment of the present disclosure;

FIG. 11 is a second structure view of the electrical connector provided by a specific embodiment of the present disclosure; and

FIG. 12 is a fourth top view of the electrical connector provided by a specific embodiment of the present disclosure.

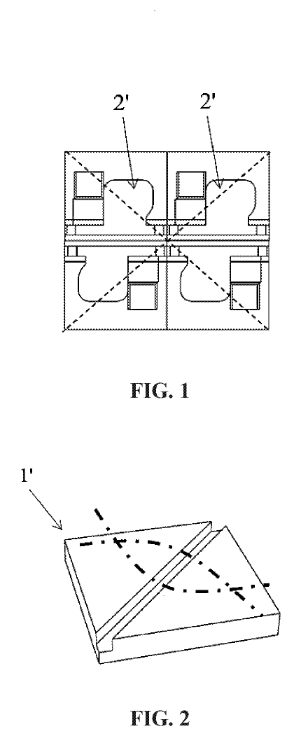

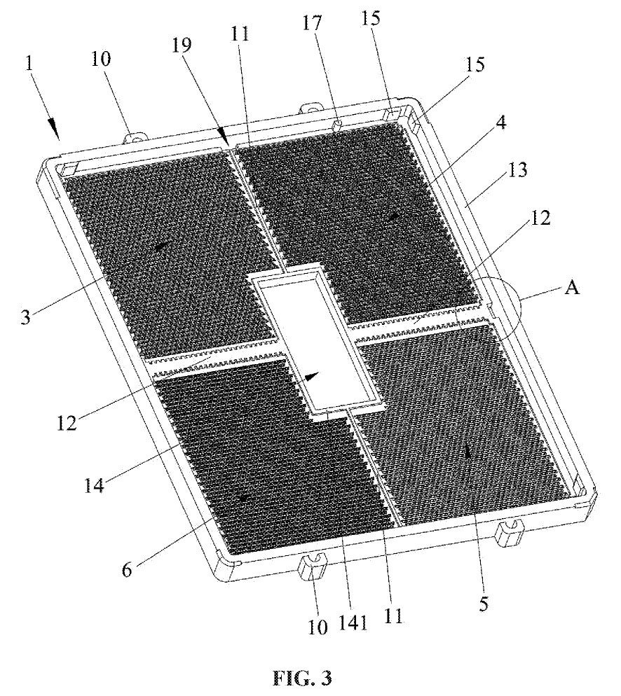

In FIGS. 1 and 2:

1′-connector body; 2′-terminal slot;

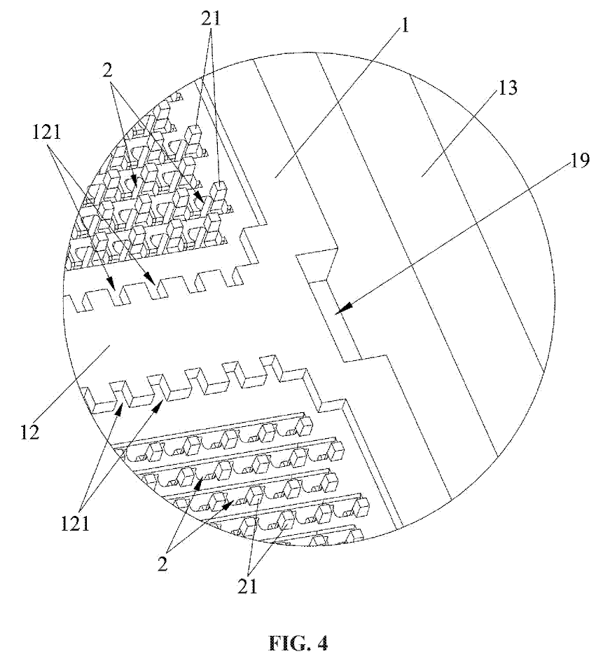

In FIGS. 3 to 12: 1-connector body; 2-terminal slot; 3-first region; 4-second region; 5-third region; 6-fourth region; 11-first support rib; 12-second support rib; 13-convex rim; 14-avoidance hole; 15-positioning protrusion; 16-third support protrusion;-in 17dication structure; 19-second avoidance groove; 10-connection portion; 121-first avoidance groove; 122-first relief groove; 131-second relief groove; 141-first support protrusion; 142-second support protrusion; 21-support boss; 100-first axis; 200-second axis.

### DETAILED DESCRIPTION

To make the technical problems solved, the technical solutions used, and the technical effects achieved in the present disclosure more apparent, the technical solutions of the present disclosure are further described below in conjunction with drawings and embodiments. Apparently, the embodiments described are only part, not all, of the embodiments of the present disclosure. Based on the embodiments of the present disclosure, all other embodiments obtained by those skilled in the art without creative work are within the scope of the present disclosure.

In the description of the present disclosure, it is to be noted that orientations or position relations indicated by terms such as "center", "upper", "lower", "left", "right", "vertical", "horizontal", "in", and "out" are based on the drawings. These orientations or position relations are intended only to facilitate and simplify the description of the present disclosure and not to indicate or imply that a device or element referred to must have such particular orientations or must be configured or operated in such particular orientations. Thus, these orientations or position relations are not to be construed as limiting the present disclosure. Additionally, terms such as "first" and "second" are used only for the purpose of description and are not to be construed as indicating or implying relative importance. The terms "first position" and "second position" are two different positions.

In the description of the present disclosure, it is to be noted that unless otherwise expressly specified and limited, the term "mounted", "connected to each other", or "connected" should be construed in a broad sense, for example, as securely connected or detachably connected; mechanically connected or electrically connected; directly connected to each other or indirectly connected to each other via an intermediary; or interconnected between two elements. For those of ordinary skill in the art, specific meanings of the preceding terms in the present disclosure may be understood based on specific situations.

### Embodiment one

As shown in FIGS. 3, 4 and 5, the present disclosure provides an electrical connector to effectively control the warpage of the electrical connector and prevent the occurrence of missing soldering in subsequent processes. The electrical connector includes a connector body 1. The connector body 1 is divided into multiple regions. Multiple terminal slots 2 are arranged in each region. Terminal slots 2 in two adjacent regions are of mirror symmetry. The terminal slot 2 is configured to enable an electrical contact to be inserted, and the electrical contact is configured to be electrically connected to a chip module.

In the electrical connector provided by the present disclosure, two adjacent regions of the connector body 1 are designed to be symmetrically arranged, and the terminal slots in the symmetric regions are designed as mirror-symmetric pairs. This causes the molded electrical connector to exhibit an overall warpage pattern of twisting along its length and width directions. Compared with the asymmetrical diagonal twisted configuration of existing electrical connectors, a lengthwise or widthwise twist is easier to correct during subsequent warpage rectification, the connector body 1 has a larger improvement space, and the warpage pattern of the finished product after the electrical contacts are inserted has less variation, thereby enabling the warpage of electrical connector products to be more stable, preventing the occurrence of missing soldering in subsequent soldering processes, avoiding poor soldering, effectively improving the production yield of the electrical connector products, and reducing the production cost of the products.

In this embodiment, the number of terminal slots 2 in two adjacent regions may be the same, that is, multiple terminal slots 2 in two adjacent regions may be of mirror symmetry in one-to-one correspondence.

In other embodiments, the number of terminal slots 2 in two adjacent regions may differ, but the difference between the two numbers is small, and the terminal slots (2) in these adjacent regions remain distributed in a mirror-symmetrical pattern. This causes the molded electrical connector to exhibit an overall warpage pattern of twisting along its length and width directions, which facilitates subsequent warpage rectification.

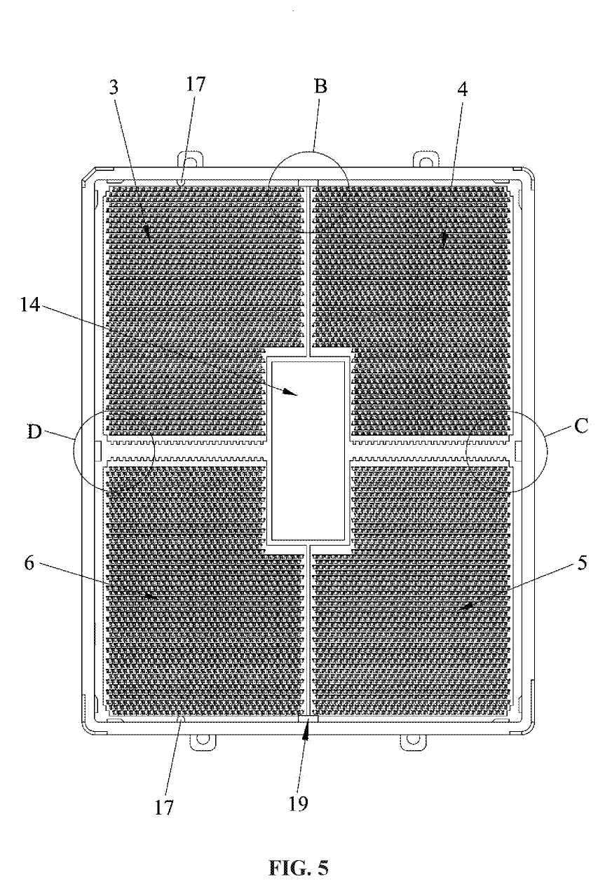

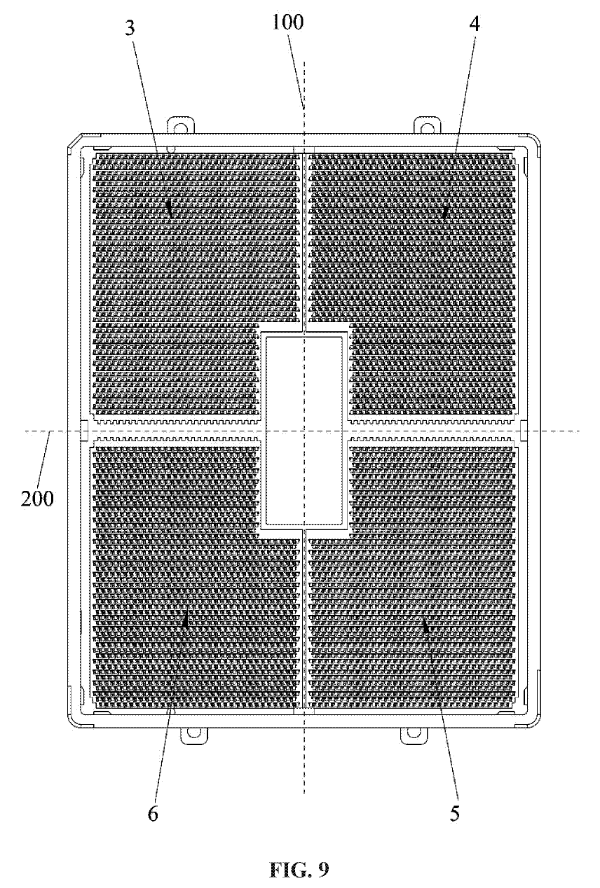

Optionally, referring to FIGS. 5 and 9, the multiple regions include a first region 3, a second region 4, a third region 5 and a fourth region 6. The first region 3 and the second region 4 are approximately symmetrical with respect to a first axis 100. The first region 3 and the fourth region 6 are approximately symmetrical with respect to a second axis 200. The second region 4 and the third region 5 are approximately symmetrical with respect to the second axis 200. The first axis 100 is perpendicular to the second axis 200. That is, the shapes of the first region 3 and the second region 4 may not be exactly the same, the shapes of the first region 3 and the fourth region 6 may not be exactly the same, and the shapes of the second region 4 and the third region 5 may not be exactly the same, as long as the areas of the four regions do not differ significantly. In this manner, when the electrical connector is subjected to bending stress, the bending axis of the electrical connector aligns with both the length and width directions of the connector body 1, and consequently, warpage rectification becomes easier to perform in subsequent processes, thereby enabling the warpage of electrical connector products to be more stable, preventing the occurrence of missing soldering in subsequent soldering processes, avoiding poor soldering, effectively improving the production yield of the electrical connector products, and reducing the production cost of the products.

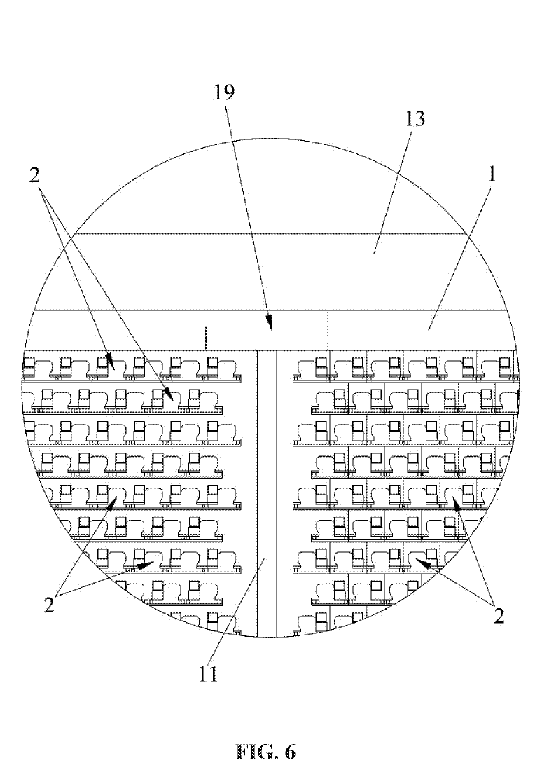

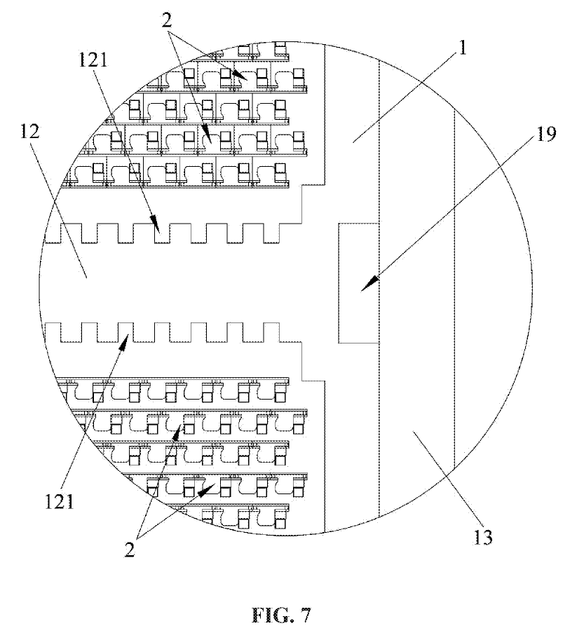

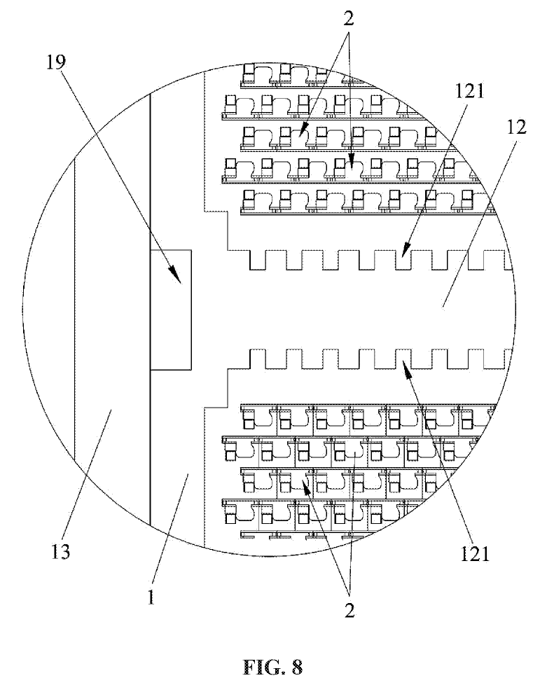

The electrical connector in this embodiment has a rectangular plate structure, four regions are separated on the electrical connector, and multiple terminal slots 2 are arranged in each region. The two dashed lines in FIG. 9 are the first axis 100 and the second axis 200, respectively. Referring to FIGS. 6 and 9, the first region 3 and the second region 4 are approximately in a left and right symmetry with respect to the first axis 100; referring to FIGS. 7 and 9, the second region 4 and the third region 5 are approximately in an upper and lower symmetry with respect to the second axis 200; referring to FIGS. 8 and 9, the first region 3 and the fourth region 6 are approximately in an upper and lower symmetry with respect to the second axis 200, and the third region 5 and the fourth region 6 are approximately in a left and right symmetry with respect to the first axis 100.

In other embodiments, the connector body 1 may be partitioned into three, five, six or the like regions, which is selected according to the design requirements of the electrical connector and is not limited to the number and arrangement exemplified in this embodiment.

Optionally, referring to FIGS. 3, 5, 6, 7 and 8, the connector body 1 is provided with first support ribs 11 arranged between the first region 3 and the second region 4 and between the third region 5 and the fourth region 6, and the first support rib 11 extends in the direction of the first axis 100 and is used for supporting the chip module. The connector body 1 is provided with second support ribs 12 arranged between the second region 4 and the third region 5 and between the first region 3 and the fourth region 6, and the second support rib 12 extends in the direction of the second axis 200 and is used for supporting the chip module. When the chip module is mounted on the connector body 1, the chip module presses against the multiple electrical contacts in the multiple terminal slots 2. The arrangement of the first support ribs 11 and the second support ribs 12 can support the chip module and limit the downward displacement of the chip module, thereby preventing excessive downward travel of the chip module against the multiple electrical contacts and protecting the electrical contacts from damage.

For example, the first supporting ribs 11 and the second support ribs 12 are convex strip structures convex on the surface of the connector body 1. In the other embodiments, the shapes of the first support ribs 11 and the second support ribs 12 may be adaptively designed according to actual requirements and are not limited to the shapes exemplified in this embodiment.

In other embodiments, the first support ribs 11 are arranged only between the first region 3 and the second region 4 and between the third region 5 and the fourth region 6 or the second support ribs 12 are arranged only between the first region 3 and the fourth region 6 and between the second region 4 and the third region 5, as long as the chip module can be supported and limited to prevent the multiple electrical contacts from damage.

Optionally, referring to FIGS. 7 and 8, multiple first avoidance grooves 121 are arranged on both sides of the second support rib 12 in the extending direction of the first axis 100, and the first avoidance groove 121 is configured to avoid the head portion of the electrical contact. The multiple first avoidance grooves 121 provide accommodation space for the head portions of the electrical contacts to prevent the head portions of the electrical contacts from being squeezed against the second support ribs 12 when the chip module is pressed down, thereby avoiding damage to the electrical contacts and ensuring good conductivity between the chip module and the circuit board. The number of first avoidance grooves 121 to be arranged is determined according to the number of terminal slots 2 arranged in the row closest to the second support rib 12 in the corresponding region.

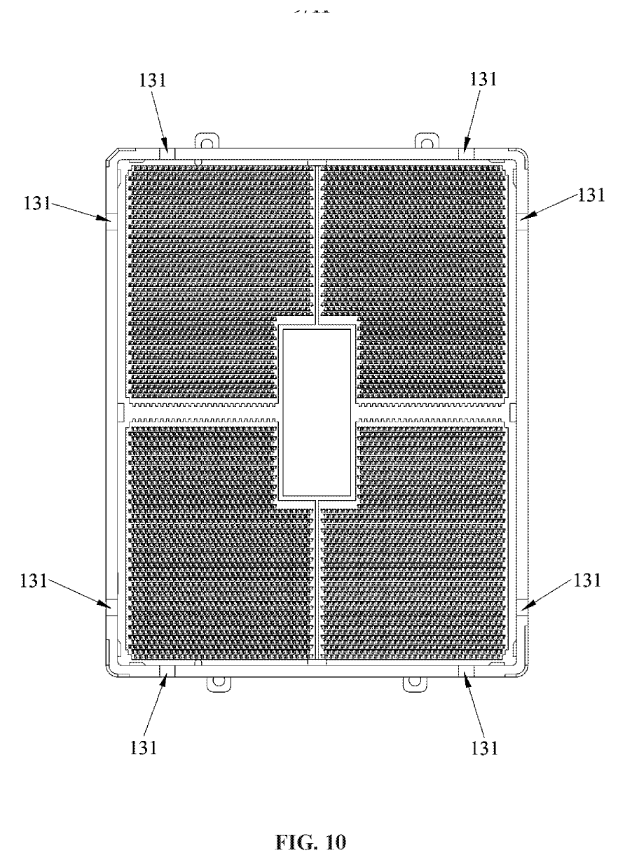

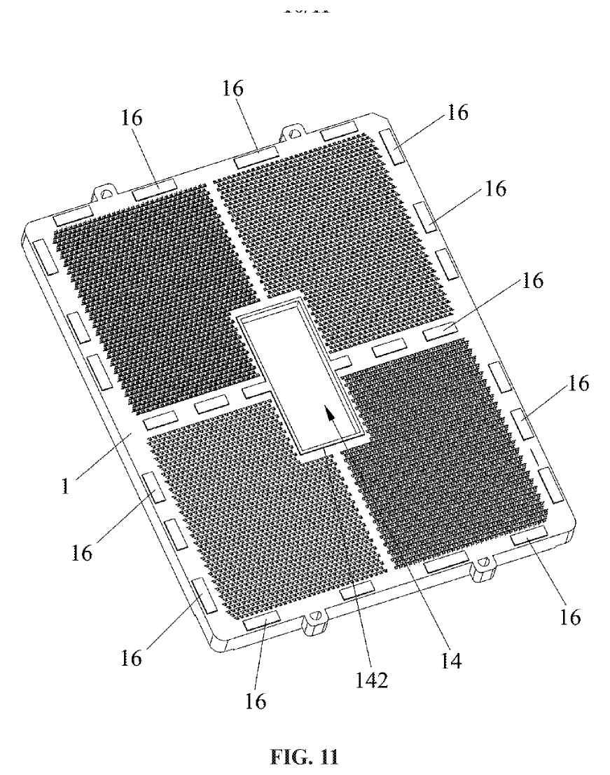

Optionally, referring to FIG. 10, a convex rim 13 protrudes upward from the outer periphery of the connector body 1 facing the chip module, multiple second relief grooves 131 are arranged on the convex rim 13, and the second relief groove 131 is used for balancing the torque of the connector body 1. Specifically, during the simulation process of the electrical connector, second relief grooves 131 may be arranged on the convex rim 13 according to twisting pattern of the connector body 1 under stress to enable the overall warpage form of the electrical connector to be rectified through the second relief grooves 131, thereby enhancing the bending resistance of the electrical connector and preventing the occurrence of missing soldering in subsequent soldering processes of the electrical connector.

For example, referring to FIG. 10, two second relief grooves 131 may be arranged at each of the four corner positions of the connector body 1. Through such an arrangement, the warpage form of the electrical connector can be further corrected to enable the warpage direction of the electrical connector to be along the length and width directions, thereby improving the soldering quality of the electrical connector. It is to be noted that the second relief grooves 131 may be arranged at the corner positions of the convex rim 13 or may also be arranged at the central positions of the convex rim 13. The number of the second relief grooves 131 to be arranged may be one, two, three or the like. The specific positions and number of the second relief grooves 131 to be arranged are determined according to the actual warpage form of the electrical connector and are not limited to the number and arrangement positions exemplified in this embodiment.

Optionally, referring to FIGS. 3 and 4, a support boss 21 is arranged on the terminal slot 2, and the support boss 21 is used for supporting the chip module. The support boss 21 can support the chip module and limit the downward displacement of the chip module to prevent the chip module from being too close to the electrical contacts, thereby avoiding excessive pressure on the electrical contacts and protecting the electrical contacts from damage.

For example, each terminal slot 2 is provided with one support boss 21 to ensure that each electrical contact is supported and protected.

Optionally, referring to FIGS. 3, 5 and 11, the connector body 1 is provided with an avoidance hole 14. The avoidance hole 14 is configured to avoid the electric component on the chip module or to avoid the electric component on the circuit board. A first support protrusion 141 is arranged circumferentially around the avoidance hole 14 on a surface of the connector body 1 facing the chip module, and the first support protrusion 141 is used for supporting the chip module. A second support protrusion 142 is arranged circumferentially around the avoidance hole 14 on a surface of the connector body 1 facing the circuit board, and the second support protrusion 142 is used for supporting the circuit board. The first support protrusion 141 can support the chip module and limit the downward displacement of the chip module to prevent the chip module from generating excessive pressure on the multiple electrical contacts, thereby protecting the electrical contacts from damage. The second support protrusion 142 can support the circuit board and limit the distance between the circuit board and the electrical connector to prevent the circuit board from being in contact with the solder balls of the electrical contacts, thereby avoiding compression damage to the solder balls and providing protection for the electrical contacts.

In this embodiment, the avoidance hole 14 is located at the central position of the connector body 1. After the chip module is placed on the connector body 1, the electric components at the center of the chip module can be precisely positioned within the avoidance hole 14, thereby avoiding interference and ensuring a reliable electrical connection between the circuit board and the chip module.

In other embodiments, the avoidance hole 14 may also be adaptively arranged on the connector body 1 according to the positions and number of electronic components on the chip module.

For example, the first support protrusion 141 and the second support protrusion 142 are both annular convex strips circumferentially arranged on the outer edge of the avoidance hole 14, and the first support protrusion 141 has the same protrusion height as the first support ribs 11, the second support ribs 12 and the support boss 21 to jointly support the chip module and limit the position of the chip module with respect to the connector body 1.

In other embodiments, third relief grooves (not shown) may also be arranged on the first support protrusion 141 and the second support protrusion 142 to enable the overall warpage form of the electrical connector to be further rectified through the third relief grooves, thereby enhancing the bending resistance of the electrical connector and ensuring the production yield of the electrical connector products.

Optionally, referring to FIG. 11, multiple third support protrusions 16 are arranged on a surface of the connector body 1 away from the chip module, and the third support protrusion 16 is configured to support the circuit board. The arrangement of the multiple third support protrusions 16 can further support the circuit board and limit the distance between the circuit board and the connector body 1 to prevent the solder balls of the multiple electrical contacts from compression damage. For example, multiple third support protrusions 16 are arranged at intervals along the outer edge of the connector body 1, between the first region 3 and the fourth region 6 and between the second region 4 and the third region 5, thereby enhancing support stability.

Further, the third support protrusions 16 are rectangular protrusions whose protrusion heights are identical to the protrusion height of the second support protrusion 142 to ensure a uniform spacing between the circuit board and the connector body 1, thereby achieving a more stable support.

Optionally, referring to FIG. 3, a positioning protrusion 15 is arranged at a corner position of the connector body 1, and the positioning protrusion 15 is used for positioning the mounting position of the chip module. The convex rim 13 encloses an accommodation space for the chip module on the connector body 1. In this embodiment, two positioning protrusions 15 are provided at each of the four corner positions of the connector body 1 and are used for preventing significant displacement of the chip module relative to the connector body 1, thereby ensuring the mounting accuracy of the chip module. For example, two positioning protrusions 15 are arranged at intervals at a corner position of the connector body 1, and the corners of the chip module are retained between these two protrusions, thereby enhancing the positioning accuracy.

Optionally, referring to FIGS. 3 and 5, an indication structure 17 is arranged in the connector body 1, and the indication structure 17 is configured to indicate the mounting direction of the chip module. The arrangement of the indication structure 17 can avoid reverse installation of the chip module, thereby preventing the electrical contacts from damage and improving the assembly quality of the products. For example, the indication structure 17 is a semi-cylinder protruding from the inner side of the convex rim 13, and correspondingly, the chip module is provided with an opening hole matched with the semi-cylinder. The chip module can be placed in the accommodation space of the connector body 1 only after the opening hole is aligned with the semi-cylinder and the semi-cylinder is engaged with the opening hole.

In other embodiments, the indication structure 17 may also be a fool-proof slot arranged on the connector body 1, and correspondingly, a protrusion matched with the fool-proof slot is arranged on the chip module. The engagement between the two plays a fool-proof role.

In this embodiment, the connector body 1 is provided with one indication structure 17 on each of its upper and lower portions. In other embodiments, the number of indication structures 17 may be adaptively increased or decreased as needed.

Further, referring to FIGS. 3 and 4, the connector body 1 is provided with second avoidance grooves 19 at the end positions of the first support rib 11 and the second support rib 12. The second avoidance groove 19 is used for avoiding the snap of a clamping device of the chip module to prevent the connector body 1 from interfering with the snap of the clamping device of the chip module, thereby ensuring a smoother assembly process for the chip module.

Optionally, referring to FIG. 3, the outer edge of the connector body 1 is also provided with a connection portion 10. The molded product of the electrical connector requires a cover (not shown) to be mounted externally, and the connection portion 10 is used for positioning the mounting position of the cover. Specifically, the cover is provided with a lug, and the lug can be engaged with the connection portion 10 for positioning to enable the cover to be accurately positioned and mounted onto the connector body 1, thereby providing protection for the electrical connector.

### Embodiment two

This embodiment provides an electrical connector. The differences between this embodiment and Embodiment one are described below.

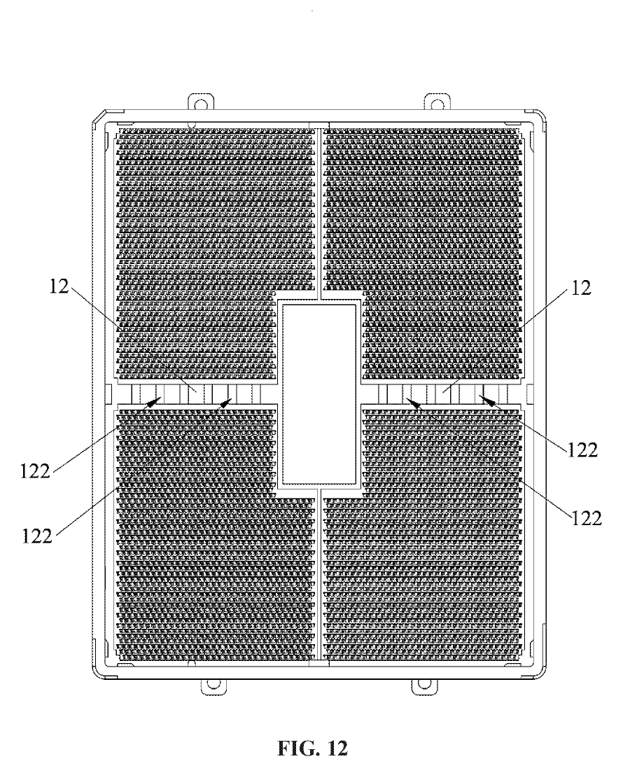

As shown in FIG. 12, in this embodiment, optionally, the second support rib 12 is provided with multiple first relief grooves 122 at intervals along the extending direction thereof, and the first relief groove 122 is used for balancing the torque of the connector body 1. During the simulation process of the electrical connector, the first relief grooves 122 may be correspondingly arranged on the second support ribs 12 according to the twisted configuration of the connector body 1 under stress to enable the overall warpage form of the electrical connector to be further rectified through the first relief grooves 122, thereby enhancing the bending resistance of the electrical connector and preventing the occurrence of missing soldering in subsequent soldering processes of the electrical connector.

The specific positions and number of the first relief grooves 122 are determined according to the actual warpage form of the electrical connector.

It is to be noted that the preceding are only preferred embodiments of the present disclosure and technical principles used therein. It is to be understood by those skilled in the art that the present disclosure is not limited to the embodiments described herein. Those skilled in the art can make various apparent modifications, adaptations, and substitutions without departing from the scope of the present disclosure. Therefore, although the present disclosure has been described in detail through the preceding embodiments, the present disclosure is not limited to the preceding embodiments and may also include other equivalent embodiments without departing from the scope of the present disclosure as determined by the scope of the appended claims.

What is claimed is:

1. An electrical connector, comprising a connector body, wherein the connector body is divided into a plurality of regions, a plurality of terminal slots are arranged in each of the plurality of regions, terminal slots in two adjacent regions are of mirror symmetry, a terminal slot of the terminal slots is configured to enable an electrical contact to be inserted, and the electrical contact is configured to be electrically connected to a chip module.

2. The electrical connector according to claim 1, wherein the plurality of regions comprise a first region, a second region, a third region and a fourth region;
the connector body is provided with first support ribs arranged between the first region and the second region and between the third region and the fourth region, and a first support rib of the first support ribs is used for supporting the chip module; and the connector body is provided with second support ribs arranged between the second region and the third region and between the first region and the fourth region, and a second support rib of the second support ribs is used for supporting the chip module.

3. The electrical connector according to claim 2, wherein a plurality of first avoidance grooves are arranged on both sides of the second support rib, and a first avoidance groove of the plurality of first avoidance grooves is configured to avoid a head portion of the electrical contact; or
the second support rib is provided with a plurality of first relief grooves at intervals along an extending direction thereof, and a first relief groove of the plurality of first relief grooves is used for balancing torque of the connector body.

4. The electrical connector according to claim 1, wherein the plurality of regions comprise a first region, a second region, a third region and a fourth region;
the connector body is provided with first support ribs arranged between the first region and the second region and between the third region and the fourth region, and a first support rib of the first support ribs is used for supporting the chip module; or the connector body is provided with second support ribs arranged between the second region and the third region and between the first region and the fourth region, and a second support rib of the second support ribs is used for supporting the chip module.

5. The electrical connector according to claim 4, wherein a plurality of first avoidance grooves are arranged on both sides of the second support rib, and a first avoidance groove of the plurality of first avoidance grooves is configured to avoid a head portion of the electrical contact; or
the second support rib is provided with a plurality of first relief grooves at intervals along an extending direction thereof, and a first relief groove of the plurality of first relief grooves is used for balancing torque of the connector body.

6. The electrical connector according to claim 1, wherein a convex rim protrudes upward from an outer periphery of the connector body facing the chip module, a plurality of second relief grooves are arranged on the convex rim, and a second relief groove of the plurality of second relief grooves is used for balancing torque of the connector body.

7. The electrical connector according to claim 1, wherein a support boss is arranged on the terminal slot, and the support boss is used for supporting the chip module.

8. The electrical connector according to claim 1, wherein the connector body is provided with an avoidance hole, the avoidance hole is configured to avoid an electric component on the chip module or to avoid an electric component on a circuit board, a first support protrusion is arranged circumferentially around the avoidance hole on a surface of the connector body facing the chip module, the first support protrusion is used for supporting the chip module, a second support protrusion is arranged circumferentially around the avoidance hole on a surface of the connector body facing the circuit board, and the second support protrusion is used for supporting the circuit board.

9. The electrical connector according to claim 1, wherein a positioning protrusion is arranged at a corner position of the connector body, and the positioning protrusion is used for positioning a mounting position of the chip module.

10. The electrical connector according to claim 1, wherein a plurality of third support protrusions are arranged on a surface of the connector body away from the chip module, and a third support protrusion of the plurality of third support protrusions is configured to support the circuit board.

11. The electrical connector according to claim 1, wherein an indication structure is arranged in the connector body, and the indication structure is configured to indicate a mounting direction of the chip module.
